(19) United States
(12) Patent Application Publication
(10) Pub. No.: US 2008/0218228 A1
(43) Pub. Date: Sep. 11, 2008

(54) Symmetrical Time/Voltage Conversion Circuit

(76) Inventor: Gilles Masson, Voreppe (FR)

Correspondence Address: BRINKS HOFER GILSON & LIONE, P.O. BOX 10395, CHICAGO, IL, 60610, US

(21) Appl. No.: 11/719,289

(22) PCT Filed: Nov. 8, 2005
(86) PCT No.: PCT/FR05/02783

§ 371 Date: Sep. 24, 2007

(30) Foreign Application Priority Data
Nov. 15, 2004 (FR) 0412082

(51) Int. Cl. H03L 7/089

(52) U.S. Cl. 327/157

(57) ABSTRACT

The invention relates to a time/voltage conversion circuit, comprising two simple time/voltage converters (CTT1 and CTT2), which are structurally-identical to each other, each having an input receiving a respective logic control signal (Up and Dwn) and an output providing a corresponding voltage representative of the duration of the logic control signal (Vup and Vdwn) and a differentiator block (BE2) with positive (302) and negative (304) inputs, each connected to a relevant simple converter (CTT1 et CTT2) and an output, providing a signal (Vdiff) representing the voltage difference between the two control signals (Up and Dwn). The output (Vdiff) from the differentiator block (BE2) is connected to an integrator block (BE3).

The present invention relates to conversion from time to voltage, referred to hereinafter as time/voltage conversion.

It finds one application in electronic circuits that have to produce clocks phase-shifted with great accuracy from a reference clock of very high frequency, typically greater than 1 GHz.

Thus it finds one application in phase-locked loop (PLL) systems or delay-locked loop (DLL) systems, in which it is necessary to convert a time offset into a proportional voltage with great accuracy.

The standard phase-locked loop system architecture is a charge pump. A charge pump generally generates from two logic signals Up (increment) and Down (decrement) a voltage proportional to the difference in the duration of the two signals. This difference is stored in order to be integrated over time.

The logic signals Up and Down are control signals from a phase detector, for example, and image the phase shift between two clock signals that it is wished to synchronize perfectly. When the two clocks have not yet been synchronized, the signals Up and Down have different durations. It is this difference in duration that it is wished to convert into a proportional voltage, and then to integrate over time, in order to correct the error by means of a feedback loop.

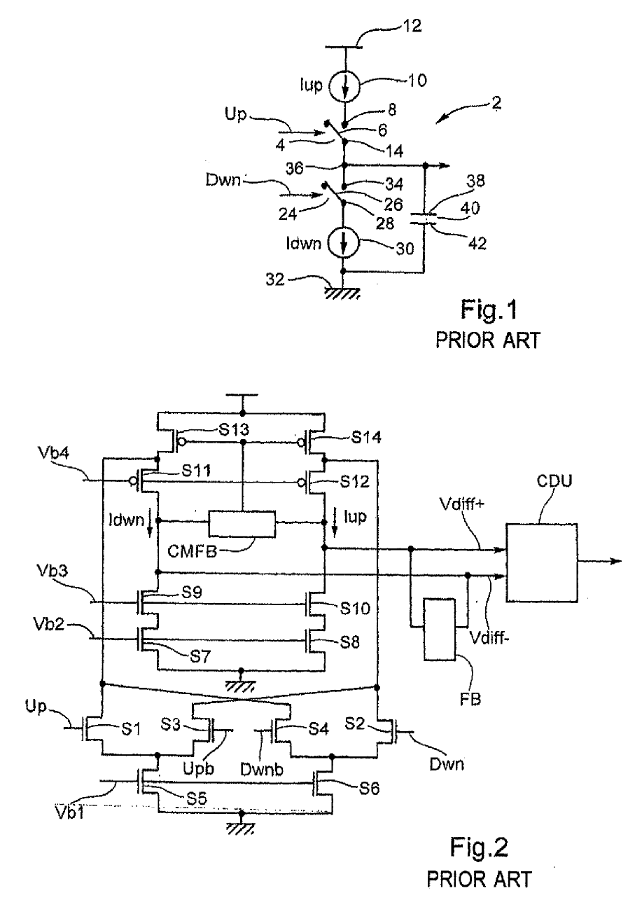

Referring to FIG. 1, a prior art conversion circuit 2 includes two switches 4 and 24. The switch 4 has a control input 6 receiving the signal Up, an input branch 8 connected to a current source 10, and an output branch 14. The current source 10 is connected to a positive power supply terminal 12. The switch 24 has a control input 26 receiving the signal Dwn, an input branch 34 and an output branch 28 connected to a current source 30. The current source 30 is connected to a power supply terminal 32 (ground). The output branch 14 of the switch 4 and the input branch 34 of the switch 24 are connected together at the node 36. One terminal 38 of a capacitor 40 is connected to the node 36. The other terminal 42 of the capacitor 40 is connected to the output of the current source 30.

If the currents Iup and Idwn from the two current sources 10 and 30 are perfectly identical, a difference in the time for which the switches 4 and 24 are closed is reflected in an increase or a decrease in the voltage at the terminals of the capacitor 40, because there is a time for which the switch 4 is open and the other switch 24 is closed (and vice-versa). The voltage difference stored in the capacitor 40 is therefore proportional to the difference in duration of the signals Up and Dwn. With this architecture, time/voltage conversion and integration are therefore effected in a simple and compact manner, but with great inaccuracy.

The inaccuracy is caused by mismatches that exist at more than one level in this type of prior art architecture.

Two types of mismatch are defined. The first type is called static mismatch SM and corresponds to the voltage drift at the capacitor 40 when the durations of the logic signals Up and Down are identical. In fact it reflects the difference between the currents Iup and Idwn that exists because of the mismatching of the current sources 10 and 30. This difference stems primarily from the fact that the current sources 10 and 30 are structurally asymmetrical, one being produced from NMOS transistors while the other is produced from PMOS transistors. The result of this is different output resistances and different bias voltages. Moreover, the efficacy of compensation developed by simulation cannot be guaranteed because of uncorrelated technological variations.

The second type of mismatch is called dynamic mismatch DM and corresponds to the voltage jump observed at the capacitor 40 when the signals Up and Dwn are switched. As for static mismatching, the error stems from the fact that the current sources 10 and 30 are structurally different, in particular the capacitances at the nodes 8 and 28 are different, even if the drain and source areas of the transistors of the source 10 of the current Iup and the source 30 of the current Idwn are made equal. What is more, the mobility of the carriers being different in NMOS and PMOS transistors, the recovery times at these nodes 8 and 28 are asymmetrical.

Moreover, if this standard structure is used at very high frequency, the contribution of the dynamic mismatch becomes high compared to other errors because it occupies a relatively greater duration in the clock cycle. What is more, dynamic mismatching (DM) cannot be compensated exactly.

The prior art architecture described hereinabove is improved by reducing the variations in the voltage at the nodes 8 and 28 and at the control inputs of the switches 4 and 24.

The integrator capacitor 40 can additionally be replaced by an active circuit including an amplifier and a capacitor connected in a feedback circuit between the negative input of the amplifier and the output of said amplifier. An active circuit of this kind maintains the output potential of the current sources constant and thus reduces static mismatching.

Other solutions have been proposed, among others in the documents U.S. Pat. No. 5,508,660 and EP 0 647 032.

In those documents an architecture is described in which the difference between the currents Iup and Idwn is read by a replica circuit operating under the same conditions as the main circuit and therefore subject to the same errors. With its polarity inverted, this error is used in a compensation loop inserted between the output of the charge pump and the bias voltages of the transistors of the current sources.

This kind of architecture can cancel out only static mismatching and is therefore not suitable for high frequencies because dynamic mismatching is not corrected. In effect, the structure is still based on a conventional charge pump in which there is a structural asymmetry between the sources of the currents Iup and Idwn because they consist of transistors of different types (NMOS and PMOS).

Also known in the art is a differential architecture like that described in the document “A 500 MHz MP/DLL Clock Generator for a 5 Gb/s Backplane Transceiver in 0.25 μs CMOS”, ISCC 2003, authors: Gu-Yeon Wei, John T. Stonick, Dan Weinlader, Jeff Sonntag and Shawn Searles.

Referring to FIG. 2, the circuit includes four control switches S1 to S4, the two control switches S1 and S2 having the signals Up and Dwn, respectively, as their control inputs, and the other two S3 and S4 having the complements Upb and Dwnb of the signals Up and Dwn, respectively, as their control inputs.

The circuit further includes eight current flow switches S5 to S12. The flow switches S5 and S6 are controlled by a bias voltage Vb1. The flow switches S7 and S5 are controlled by a bias voltage Vb2. The flow switches S9 and S10 are controlled by a bias voltage Vb3. The flow switches S11 and S12 are controlled by a bias voltage Vb4.

Switches S13 and S14 are controlled by a common mode feedback (CMFB) block. The block CMFB controls the common output mode, i.e. the mean level of the bias voltages Vb1 to Vb4 that define the levels of the currents Iup and Idwn.

When the signals Up and Down are of the same polarity, no current flows in the loop filter FB, and the system is in equilibrium.

If the signals Up and Dwn are of opposite polarity, the currents Iup and Idwn flow in the loop filter FB and are integrated to produce a differential voltage (Vdiff+−Vdiff−). This differential voltage is converted into a signal for controlling a delay line by a converter CDU.

The structure of this differential architecture is symmetrical in that the currents Iup and Idwn are generated using transistors of identical type and size.

Similarly, the control transistors of the current flow switches S5 to S12 are identical for the signals Up and Dwn.

The structure therefore reduces dynamic mismatching by balancing the injections of charge at the time of switching.

The drawbacks of this kind of structure are, on the one hand, the necessity to control the common output mode (block CMFB) and, on the other hand, the design of a differential to unipolar conversion block CDU. These two blocks CMFB and CDU, which are difficult to design, generate additional mismatches and contribute to increasing the static mismatch.

The present invention solves these problems.

It is directed to a time/voltage converter adapted to convert the difference in the duration of two logic signals into a proportional voltage with great accuracy at high frequencies, typically frequencies greater than 1 GHz.

According to a general definition of the invention, the time/voltage conversion circuit includes two structurally identical basic time/voltage converters each having an input receiving a respective logic control signal and an output delivering a voltage representative of the duration of the corresponding logic control signal and a differentiator block having positive and negative inputs each connected to an output of an associated basic converter and an output delivering a signal representative of the voltage difference between the two control signals.

This kind of structure eliminates the structural asymmetry that exists between the generation of the sources of currents Iup and the sources of currents Idwn in the architecture described with reference to FIG. 1.

Similarly, this kind of structure uses no compensation loop associated with this asymmetry as in the differential processing of the architecture described with reference to FIG. 2.

In effect, the circuit according to the invention proposes an architecture that is completely symmetrical in the phase of switching the signals generally responsible for dynamic mismatching and that is quasi-symmetrical in the static phase.

Thus the invention eliminates dynamic and static mismatches by structural means.

Thus the technique used in accordance with the invention has better immunity to noise carried by the power supplies and the substrate because the structure is perfectly symmetrical for operations that necessitate great accuracy. In effect, spuriae are thus found on the two channels and are subtracted by a differentiator block.

Other features and advantages of the invention will become apparent in the light of the following detailed description and the drawings in which:

FIG. 1, already described, shows an architecture of a prior art time/voltage converter;

FIG. 2, already described, shows an architecture of a prior art differential time/voltage converter;

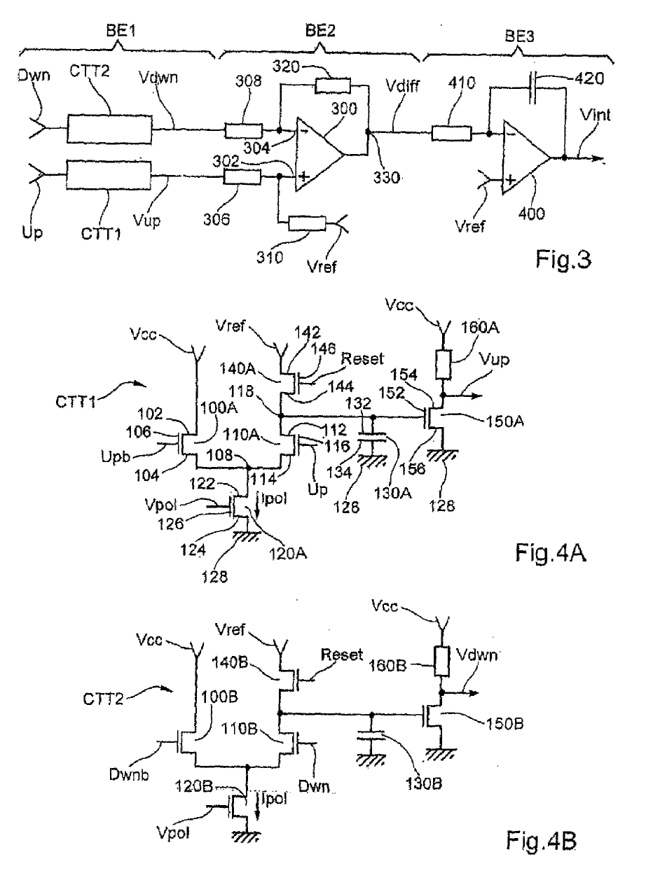

FIG. 3 shows diagrammatically a symmetrical time/voltage converter according to the invention;

FIGS. 4A and 4B show in detail a basic time/voltage converter according to the invention;

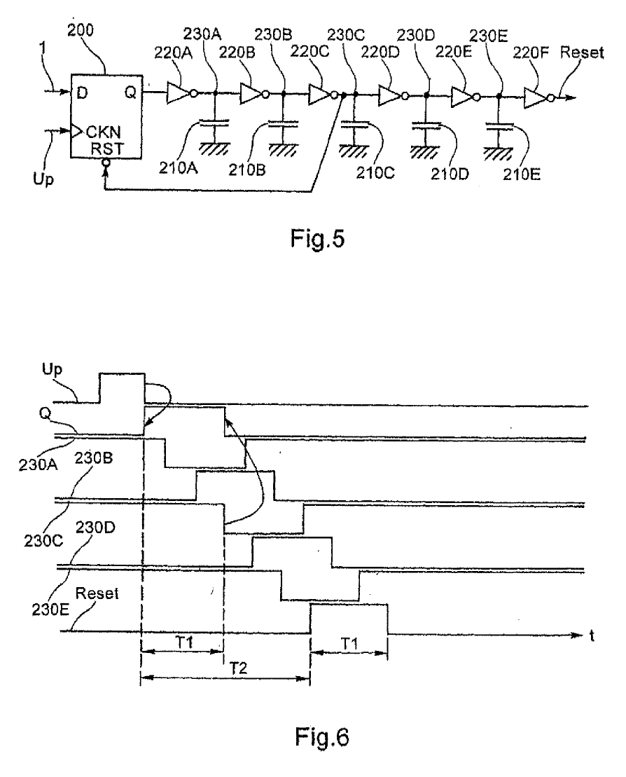

FIG. 5 shows diagrammatically a reset pulse generator according to the invention;

FIG. 6 shows timing diagrams of signals for resetting the generator from FIG. 5;

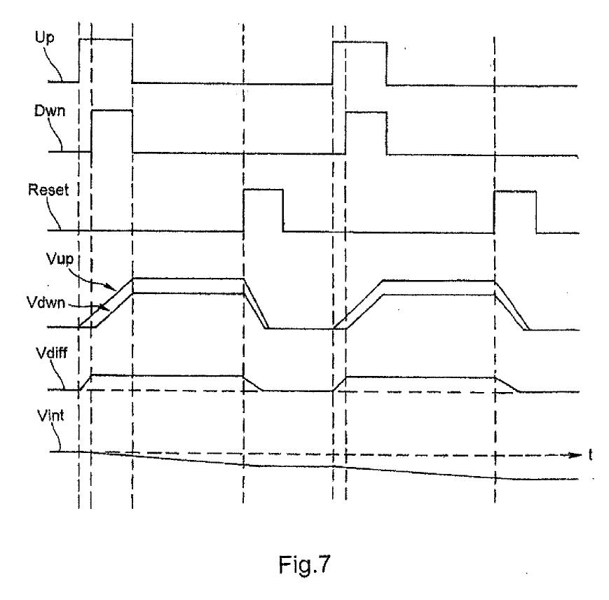

FIG. 7 are timing diagrams of signals of the symmetrical time/voltage conversion architecture according to the invention; and

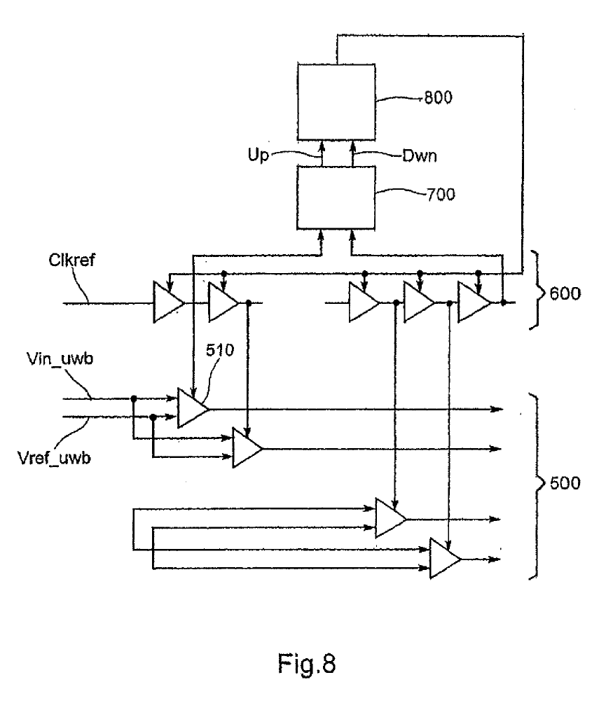

FIG. 8 is a block diagram of the analog-digital conversion architecture using a converter according to the invention.

Referring to FIG. 3, the time/voltage conversion and integration operations are divided into three elementary blocks BE1 to BE3.

The first block BE1 relates to time/voltage conversion on two separate channels. The intermediate block BE2 relates to the subtraction of the voltages of the channels and the terminal block BE3 relates to the integration of the difference.

The conversion block BE1 executes signal switching operations in a perfectly symmetrical manner for the separate channels, which completely eliminates structural dynamic mismatching.

The conversion block BE1 includes two identical, separate and symmetrical basic time/voltage converters CTT1 and CTT2 in parallel. Each basic converter CTT1 and CTT2 has an input receiving a respective polarity control signal Up or Dwn and an output delivering a voltage Vup or Vdwn representative of the duration of each control signal.

Referring to FIG. 4A, the basic time/voltage converter CTT1 includes:
a first switch (transistor) 100A having an input branch 102 (drain) connected to a positive first power supply terminal Vcc, an output branch 104 (source) connected to a first intermediate node 108, and a control input 106 (gate) receiving a control signal Upb,
a second switch (transistor) 110A having an input branch 112 connected to a second intermediate node 118, an output branch 114 (source) connected to the first intermediate node 108, and a control input 116 (gate) receiving the complement Up of the control signal Upb of the first switch 100A,
a current source (transistor) 120A producing a current Ipol and having an input branch 122 (drain) connected to the first intermediate node 108, an output branch 124 (source) connected to a second power supply terminal 128 (ground), and a control input 126 (gate) connected to a third power supply terminal Vpo1,
a capacitor 130A having a first terminal 132 connected to the second intermediate node 118 and a second terminal 134 connected to the second power supply terminal 128,
a third switch (transistor) 140A having an input branch (drain) 142 connected to a fourth power supply terminal Vref, an output branch (source) 144 connected to the second intermediate node 118, and a control input 146 (gate) receiving a signal Reset for resetting the capacitor to the value at the fourth power supply terminal Vref,
a voltage amplifier (transistor) 150A having a control input (gate) 152 connected to the second intermediate node 118 and an output (drain) 154 delivering the voltage Vup representative of the duration of the control signal Up, the source 156 of the transistor 150A being connected to ground 128 and the drain 154 being connected to the power supply terminal Vcc via a resistor 160A.

Referring to FIG. 4B, the basic time/voltage converter CTT2 has a structure identical to that of the converter CTT1 from FIG. 4A. The components of the converter CTT2 carry the same reference numbers as those of the converter CTT1 followed by the letter B. The converter CTT2 is associated with the control signal Dwn and its complement Dwnb.

The sources 120A and 120B of the current Ipol draw current from the power supply terminal vcc when the control signals of the switches 100A and looB Upb and Dwnb are active or the capacitors 130A and 130B when the control signals of the switches 110A Up and 110B Dwn are active. The signals Upb and Dwnb are the inverted or complemented equivalents of the signals Up and Dwn. The voltages Vup and Vdwn at the terminals of the capacitors 130A and 130B are therefore proportional to the time for which the switches 110A and 110B are closed and therefore to the durations of the signals Up and Dwn.

These voltages Vup and Vdwn are then amplified and reshaped by the amplifiers 150A and 1503 before being transmitted to the subtractor block BE2.

The capacitors 130A and 130B store the voltages before amplification and are reset to the voltage Vref by the Reset signal. The voltages are amplified by the transistors 150A and 150B and the resistors 160A and 160B.

The voltage Vpo1 sets a current Ipo1 in each basic converter CTT. The voltage Vcc is the general power supply voltage. The voltage Vref is a reference voltage lower than the power supply voltage Vcc.

Time/voltage conversion uses a reset phase during which the capacitors 130A and 130B are reset to a reference value Vref.

In practice, the switches are produced from MOS technology transistors. For example, all the switches of the converters CTT1 and CTT2 are produced from NMOS transistors.

The complemented control signals are in practice generated by means of inverters.

Referring to FIG. 5, the reset control signal Reset is generated from the signal Up or the signal Dwn by a specific block, for example, that includes an edge-triggered flip-flop 200 and delay cells connected in series and each consisting of inverters 220 individually denoted 220A to 220E and capacitors 210 individually denoted 210A to 210E.

For example, the resetting signal Reset is generated on the rising edge of the signal Up. This resetting signal can also be generated from the signal Dwn, because the falling edges of the signals Up and Dwn are synchronous. This property is linked to the use of the phase comparator 700.

Referring to FIGS. 5 and 6, the falling edge of the signal Up triggers the clock input CKN of the edge-triggered flip-flop 200. The output Q, previously set to 0, goes to the level present at the input D, that is to say 1. The signal Q is then delayed several times by the capacitors 210A, 210B2 and 210C, The signal present at the node 230C goes to 0 and resets to 0 the RST input of the edge-triggered flip-flop 200 at the end of a time T1 that corresponds to the duration of the resetting pulse.

The pulse is then delayed several times again by the capacitors 210D and 210E. The sum of all the delays gives the time T2, which corresponds to the starting time of the resetting pulse Reset.

FIG. 3 is referred to again. Time/voltage conversion is symmetrical, the voltage difference Vup−Vdwn is produced continuously by the block BE2 including a subtractor amplifier 300 having a positive input 302 receiving the voltage Vup via a resistor 306 and a negative input 304 receiving the voltage Vdown via a resistor 308. The reference voltage Vref also feeds the positive input 302 via a resistor 310 and the output 330 is connected to the negative input 304 via a resistor 320.

The difference is integrated continuously by an integrator BE3 including an active circuit amplifier 400 of the resistor 410 and capacitor 420 type.

Referring to FIG. 7, the timing diagrams are shown for a signal Up having a duration greater than the signal Dwn. After time/voltage conversion in accordance with the invention, the voltages Vup and Vdwn have different levels proportional to the duration of the signals Up and Dwn. These voltages are reset to a reference level by the resetting signal Reset.

The difference Vdiff=Vup−Vdwn is therefore positive and increments the output voltage Vint of the integrator BE3. Here the voltage Vint changes in the opposite direction to Vdiff because the integrator circuit is an inverter circuit.

The present invention can be integrated into the digitization technique used in the receive channel of an ultra wide band (UWB) transmitter. This technique digitizes on 1 bit a UWB signal at the frequency of 20 GHZ.

Referring to FIG. 8, the conversion architecture of a UWB system includes a 1-bit 20 GHz analog-digital converter 500 and a delay-locked loop (DLL). That loop includes voltage-controlled delay lines 600, a phase comparator 700 and a time/voltage converter 800 produced in accordance with the invention.

The 1-bit conversion at 20 GHz is effected at lower frequency because of technological limitations. For example 16 clocks are generated at the frequency of 1.25 GHz, offset by 50 ps. There is obtained in this way a 1-bit analog-digital converter operating at 20 GHz consisting of 16 comparators connected in parallel and controlled by the 16 offset clocks.

One critical point for the overall accuracy of the system is the 50 ps offset. It is necessary to use a phase-locked loop to control this delay and to generate the 16 clocks.

The analog signal to be converted is Vin_uwb. It is compared to a voltage Vref_uwb by 16 comparators 510 in parallel that are activated at the frequency of 1.25 GHz with a 50 ps offset. The results of the 16 conversions are sent to a logic unit for reshaping and processing.

The 16 clocks offset by 50 ps are generated by the phase-locked loop, consisting of a voltage-controlled delay line 600, a phase comparator 700, and a time/voltage converter 800 produced in accordance with the invention.

The circuit 800 according to the invention integrated into the phase-locked loop between the phase comparator 700 that generates the signals Up and Dwn and the voltage-controlled delay line 600 therefore provides the accuracy required at the operating frequency of 1.25 GHz.

The technique used in accordance with the invention has better immunity to noise carried on the power supplies and the substrate because the structure is perfectly symmetrical for operations that necessitate great accuracy. In effect, spuriae are therefore found on the two channels CTT1 and CTT2 and are subtracted by the differentiator block BE2.

1. Time/voltage conversion circuit including two structurally identical basic time/voltage converters (CTT1 and CTT2) each having an input receiving a respective logic control signal (Up and Dwn) and an output delivering a voltage representative of the duration of the corresponding logic control signal (Vup and Vdwn) and a differentiator block (BE2) having a positive input (302) and a negative input (304) each connected to an output of an associated basic converter (CTT1 and CTT2) and an output delivering a signal (Vdiff) representative of the voltage difference between the two control signals (Up and Dwn).

2. Circuit according to claim 1, wherein the output of the differentiator block is connected to an integrator block (BE3).

3. Circuit according to claim 1, wherein the differentiator block (BE2) is a subtractor amplifier (300).

4. Circuit according to claim 2 or claim 3, wherein the integrator block (BE3) is an active amplifier (400) of RC type.

5. Circuit according to any one of claims 1 to 4, wherein the control signals (Up and Dwn) are obtained from a phase comparator (700).

6. A circuit according to claim 1, characterized in that each basic time/voltage converter (CTT1 and CTT2) includes:
a first switch (100A, 100B) having an input branch (102) connected to a first power supply terminal (Vcc), an output branch (104) connected to a first intermediate node (108), and a control input (106) receiving a control signal (Upb, Dwnb);
a second switch (110A, 110B) having an input branch (112) connected to a second intermediate node (118), an output branch (114) connected to the first intermediate node (108), and a control input (116) receiving the complement (Up, Dwn) of the control signal (Upb, Dwnb) of the first switch (100A, 100B);
a current source (120A, 120B) including an input branch (122) connected to the first intermediate node (108), an output branch (124) connected to a second power supply terminal (128), and a control input (126) connected to a third power supply terminal (Vpo1);
a capacitor (130A, 130B) having a first terminal (132) connected to the second intermediate node (118) and a second terminal (134) connected to the second power supply terminal (128);
a third switch (140A, 140B) having an input branch (142) connected to a fourth power supply terminal (Vref), an output branch (144) connected to the second intermediate node (118), and a control input (146) receiving a signal (Reset) for resetting the capacitor to the value at the fourth power supply terminal (Vref);
a voltage amplifier (150A, 150B) having a control input (152) connected to the second intermediate node (118) and an output (154) delivering the voltage (Vup, Vdwn) representative of the duration of the control signal (Up, Dwn).

7. Circuit according to claim 6, wherein the resetting signal (Reset) is produced by an edge-triggered flip-flop (200) and delay cells (210, 220).
